(19) United States
(12) Patent Application Publication
(10) Pub. No.: US 2025/0226303 A1
(43) Pub. Date: Jul. 10, 2025

(54) FLEXIBLE CIRCUIT BOARD, COF MODULE, AND ELECTRONIC DEVICE COMPRISING SAME

(71) Applicant: LG INNOTEK CO., LTD., Seoul (KR)

(72) Inventors: Ki Tae PARK, Seoul (KR); Chae Won KANG, Seoul (KR); Dong Chan KIM, Seoul (KR)

(21) Appl. No.: 18/879,647

(22) PCT Filed: Apr. 3, 2023
(86) PCT No.: PCT/KR2023/004444

§ 371 Date: Dec. 27, 2024

(30) Foreign Application Priority Data
Jun. 27, 2022 (KR) 10-2022-0078341

(51) Int. Cl. H01L 23/498

(52) U.S. Cl. CPC H01L 23/49838; H01L 23/4985

(57) ABSTRACT

A COF module according to an embodiment comprises a substrate including a chip mounting region; a circuit pattern disposed on the substrate; and a chip disposed on the chip mounting region and connected to the circuit pattern, wherein the circuit pattern includes a first circuit pattern, a second circuit pattern, and a third circuit pattern, wherein the third circuit pattern is disposed inside the chip mounting region, wherein a first terminal part of the chip is connected to the third circuit pattern, and wherein an end of the first terminal part and an end of the third circuit pattern are spaced apart from each other.

### TECHNICAL FIELD

An embodiment relates to a flexible circuit board, a COF module and an electronic device including the same. In detail, the flexible circuit board may be a flexible circuit board for COF.

### BACKGROUND ART

Recently, various electronic products are becoming thinner, smaller, and lighter. Accordingly, various studies are being conducted to mount a semiconductor chip in a narrow region of the electronic product with high density.

COF (Chip On Film) uses a flexible substrate. Accordingly, the COF is applied to a flexible display. That is, a COF method is applied to various wearable electronic devices. In addition, the COF can implement a fine pitch. Therefore, the COF can be applied to a high-resolution display.

The COF is formed by mounting a semiconductor chip on a flexible circuit board in a form of a thin film. For example, the semiconductor chip may include an integrated circuit (IC) chip or a large scale integrated circuit (LSI) chip.

Meanwhile, the chip is connected to an external printed circuit board and a display panel by a circuit pattern. For example, pad parts are disposed on one end and another end of the circuit pattern, respectively. In addition, one pad part is electrically connected to a terminal of the chip. In addition, another pad part is connected to a terminal of the printed circuit board and a terminal of the display panel. Accordingly, the chip, the printed circuit board, and the display panel are electrically connected by the COF. In addition, a signal is transmitted to the display panel by the circuit pattern.

As described above, the COF can be formed by mounting a semiconductor chip on a flexible circuit board. A process of mounting the chip is performed within a set temperature range. Accordingly, when connecting the pad part of the chip and the circuit pattern, the substrate may contract.

Accordingly, an alignment of the chip and the circuit pattern may be misaligned. In addition, electrical characteristics of the COF module may be reduced.

To solve the above problem, a solder may be disposed at a position considering that the substrate is contracted before the chip and the circuit pattern are bonded. Subsequently, the chip and the circuit pattern may be bonded. However, a position of a connection region between the chip and the circuit pattern may be changed by a correction. Accordingly, a length of the pad part may be unnecessarily increased. In addition, a distance between adjacent patterns may be reduced.

### DISCLOSURE

### Technical Problem

An embodiment provides a COF module having improved electrical characteristics while satisfying an alignment of a chip and a circuit pattern.

### Technical Solution

A COF module according to an embodiment comprises a substrate including a chip mounting region; a circuit pattern disposed on the substrate; and a chip disposed on the chip mounting region and connected to the circuit pattern, wherein the circuit pattern includes a first circuit pattern, a second circuit pattern, and a third circuit pattern, wherein the third circuit pattern is disposed inside the chip mounting region, wherein a first terminal part of the chip is connected to the third circuit pattern, and wherein an end of the first terminal part and an end of the third circuit pattern are spaced apart from each other.

### Advantageous Effects

The COF module according to the embodiment has improved connection characteristics. In detail, when connecting the pad part of the chip and the circuit pattern, the COF module has improved connection characteristics while maintaining alignment.

That is, a terminal part of the chip is separated from an end of the pad part of the circuit pattern. Accordingly, all of the terminal parts of the chip are connected to the pad part.

In addition, a separation distance between an end of the terminal part of the chip and the end of the pad part of the circuit pattern satisfies a set range. Accordingly, the length of the pad part can be prevented from increasing. Accordingly, a size of the chip mounting region can be reduced. In addition, a spacing between adjacent circuit patterns can be secured at a sufficient distance.

In addition, the terminal part of the chip includes an overlapping region and a non-overlapping region. The overlapping region overlaps the circuit pattern in a width direction of the circuit pattern. In addition, the non-overlapping region does not overlap the circuit pattern in the width direction of the circuit pattern.

A width of the non-overlapping region satisfies a set range. That is, the width of the non-overlapping region has a range set with respect to a width of the pad part. In addition, the width of the non-overlapping region has a range set with respect to the width of the overlapping region. Accordingly, the connection characteristics of the terminal part of the chip and the pad part are improved.

In addition, the width of the non-overlapping region is smaller than a spacing of the pad part or a spacing of the terminal part. Accordingly, the spacing of the pad part or the spacing of the terminal part can be prevented from being reduced by the non-overlapping region. Accordingly, it can prevent short circuits between adjacent pad parts. Alternatively, it can prevent short circuits between adjacent terminal parts.

### DESCRIPTION OF DRAWINGS

FIG. 1 is a top view of a COF module including a flexible printed circuit board according to an embodiment.

FIGS. 2 and 3 are cross-sectional views taken along region A-A′ of FIG. 1.

FIG. 4 is a cross-sectional view taken along region B-B′ of FIG. 1.

FIG. 5 is a drawing for explaining region A of FIG. 1.

FIGS. 6 and 7 are drawings for explaining regions B and C of FIG. 5.

FIG. 8 is a drawing for explaining region D of FIG. 5.

FIG. 9 is a cross-sectional view showing a connection relationship of a COF module including a flexible printed circuit board according to an embodiment.

FIGS. 10 to 12 are drawings for electronic devices including a flexible printed circuit board according to an embodiment.

### MODE FOR INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a flexible circuit board, a COF module, and an electronic device including the same according to an embodiment will be described with reference to the drawings.

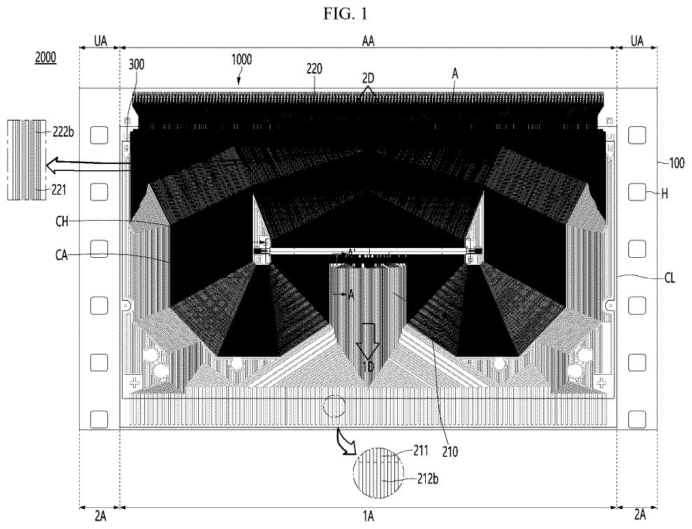

FIG. 1 is a top view of a COF module including a flexible circuit board according to an embodiment.

Referring to FIG. 1, the COF module 2000 includes a flexible printed circuit board 1000 and a chip CH. In detail, the flexible printed circuit board 1000 includes a chip mounting region CA. The chip CH is disposed on the chip mounting region CA.

The flexible printed circuit board 1000 includes a substrate 100 and a circuit pattern 200 disposed on the substrate 100.

The substrate 100 may include a flexible substrate. For example, the substrate 100 may be a polyimide (PI) substrate. However, the embodiment is not limited thereto. The substrate 100 may include a polymer material such as polyethylene terephthalate (PET) or polyethylene naphthalate (PEN). Accordingly, the flexible circuit board including the substrate 100 may be applied to various electronic devices including a curved display device. For example, the flexible circuit board has excellent flexible characteristics. Therefore, the flexible circuit board may be applied to a wearable electronic device.

A thickness of the substrate 100 may be 20 um to 100 um. For example, the thickness of the substrate 100 may be 25 um to 50 um. For example, the thickness of the substrate 100 may be 30 um to 40 um. If the thickness of the substrate 100 exceeds 100 um, the thickness of the flexible circuit board may increase. Accordingly, the flexible characteristics of the flexible circuit board are reduced. In addition, if the thickness of the substrate 100 is less than 20 um, a rigidity of the substrate may decrease. Accordingly, when mounting a chip on the substrate, the substrate 100 may be damaged by heat and pressure.

The substrate 100 includes an effective region UA and an ineffective region UA. The effective region AA may be a central region of the substrate 100. The ineffective region UA may be an edge region of the substrate 100. The ineffective region UA may surround the effective region AA.

The effective region AA includes a chip mounting region CA. In detail, the chip mounting region CA is a region where a chip CH connected to the circuit pattern is mounted.

In addition, a circuit pattern 210, 220, and 230 is disposed on the effective region AA. In detail, the circuit pattern includes a plurality of circuit patterns. The plurality of circuit patterns extend in a plurality of directions. In addition, the plurality of circuit patterns are spaced apart from each other.

The effective region AA is a region that is actually used in the flexible circuit board 1000.

The circuit pattern is not disposed on the ineffective region UA. That is, the effective region AA and the ineffective region UA are distinguished by an arrangement of the circuit pattern.

The ineffective region UA includes a plurality of holes. In detail, the ineffective region UA includes a plurality of sprocket holes H. The flexible circuit board is rolled or unrolled in a roll-to-roll manner by the sprocket holes.

The ineffective region UA is a region that is not actually used in the flexible circuit board 1000. In detail, the ineffective region UA is a region that is removed after manufacturing the COF module.

In detail, a boundary between the effective region AA and the ineffective region UA is defined by a cutting line CL. The flexible circuit board 1000 is processed into a COF module after cutting the cutting line CL. Accordingly, the flexible circuit board 1000 is applied to various electronic devices.

The circuit pattern includes a wiring part and a pad part. In addition, a plurality of circuit patterns are disposed on the effective region AA. In detail, a first circuit pattern 210, a second circuit pattern 220, and a third circuit pattern 230 are disposed on the effective region AA.

The first circuit pattern 210, the second circuit pattern 220 are disposed on an inner region of the chip mounting region CA and an outer region of the chip mounting region CA. The third circuit pattern 230 is disposed on the inner region of the chip mounting region CA.

Referring to FIGS. 1 to 3, the first circuit pattern 210 includes a first wiring part 211, a first pad part 212a, and a second pad part 212b. The first pad part 212a is disposed inside the chip mounting region CA. The second pad part 212b is disposed outside the chip mounting region CA. The first wiring part 211 is disposed between the first pad part 212a and the second pad part 212b. The first wiring part 211 is connected to the first pad part 212a and the second pad part 212b.

The first wiring part 211, the first pad part 212a, and the second pad part 212b are formed integrally.

In addition, the first wiring part 211 extends in a first direction 1D based on the chip mounting region CA.

The first pad part 212a is electrically connected to a chip disposed in the chip mounting region. In addition, the second pad part 212b is electrically connected to a printed circuit board. In addition, the first wiring part 211 transmits a signal between the chip and the printed circuit board.

A protective layer 300 is disposed on the first circuit pattern 210. In detail, the protective layer 300 is disposed on the first wiring part 211. The protective layer 300 is disposed while surrounding the first wiring part 211. In addition, the protective layer 300 is not disposed on the first pad part 212a and the second pad part 212b. Accordingly, the first pad part 212a and the second pad part 212b are exposed to an outside.

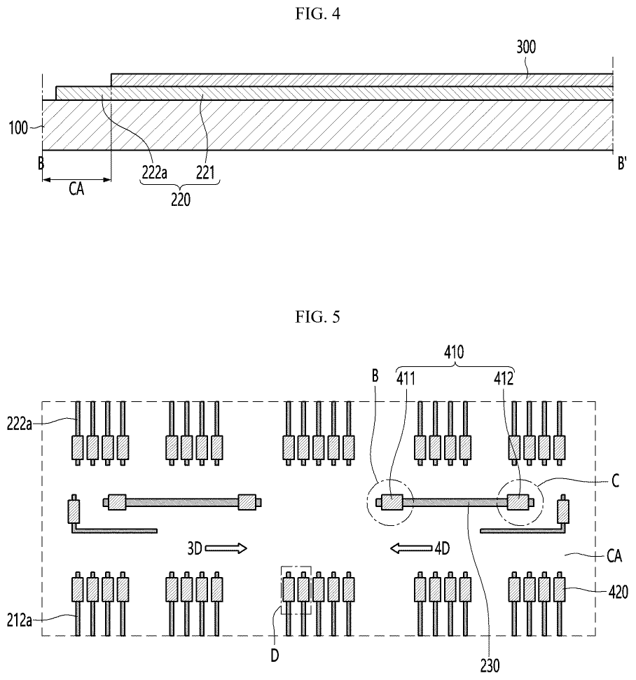

Referring to FIG. 1 and FIG. 4, the second circuit pattern 220 includes a second wiring part 221, a third pad part 222a, and a fourth pad part 222b. The third pad part 222a is disposed inside the chip mounting region CA. The fourth pad part 222b is disposed outside the chip mounting region CA. The second wiring part 221 is disposed between the third pad part 222a and the fourth pad part 222b. In addition, the second wiring part 221 is connected to the third pad part 222a and the fourth pad part 222b.

The second wiring part 221, the third pad part 222a, and the fourth pad part 222b are formed integrally.

In addition, the second wiring part 221 extends in a second direction D2 based on the chip mounting region CA. In detail, the second direction D2 is an opposite direction to the first direction D1.

The third pad part 222a is electrically connected to a chip disposed in the chip mounting region. In addition, the fourth pad part 222b is electrically connected to the display panel. In addition, the second wiring part 221 transmits a signal between the chip and the display panel.

A protective layer 300 is disposed on the second circuit pattern 220. In detail, the protective layer 300 is disposed on the second wiring part 221. The protective layer 300 is disposed while surrounding the second wiring part 221. In addition, the protective layer 300 is not disposed on the third pad part 222a and the fourth pad part 222b. Accordingly, the third pad part 222a and the fourth pad part 222b are exposed to an outside.

The third circuit pattern 230 may include the third wiring part and a plurality of pad parts. In detail, the third wiring part and the plurality of pad parts are disposed inside the chip mounting region CA.

The third circuit pattern 230 is connected to the chip CH disposed in the chip mounting region CA. In detail, the plurality of pad parts of the third circuit pattern 230 are electrically connected to the chip CH. In detail, the third circuit pattern 230 includes a plurality of circuit patterns. Each of the third circuit patterns 230 includes a plurality of pad parts. The pad part of each of the third circuit patterns is electrically connected to the chip CH.

The third circuit pattern 230 may be a routing pattern. That is, the third circuit pattern 230 can function as one of layers of the chip.

The third circuit pattern 230 is connected to the chip CA by the plurality of pad parts. Accordingly, the third circuit pattern 230 can receive and process a signal transmitted from the first circuit pattern 210. A signal transmitted from the third circuit pattern 230 through the chip CH and the second circuit pattern 220 is transmitted to the display panel.

The first circuit pattern 210 and the second circuit pattern 220 may include a metal material having excellent electrical conductivity. In detail, the first circuit pattern 210 and the second circuit pattern 220 may include copper (Cu). However, the embodiment is not limited thereto. The first circuit pattern 210 and the second circuit pattern 220 may include at least one metal among copper (Cu), aluminum (Al), chromium (Cr), nickel (Ni), silver (Ag), molybdenum (Mo), gold (Au), titanium (Ti), and alloys thereof.

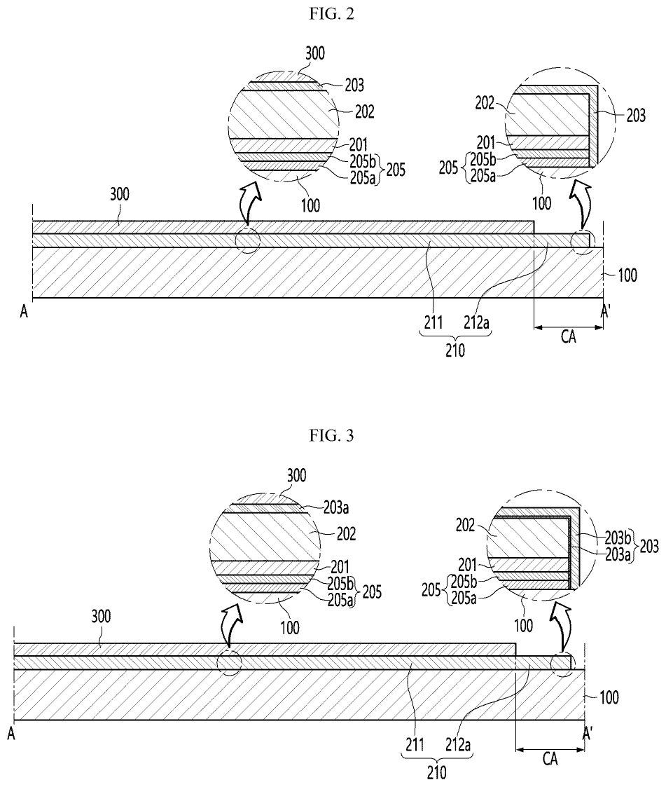

Hereinafter, with reference to FIGS. 2 and 3, a layer structure of the circuit pattern of the flexible circuit board according to the embodiment will be described. In FIGS. 2 and 3, the first circuit pattern 210 will be described. However, the embodiment is not limited thereto. A description of the layer structure below also applies to the second circuit pattern 220.

Referring to FIG. 2, the first circuit pattern 210 is formed in multiple layers. In detail, the first wiring part 211 and the first pad part 212a include a first metal layer 201 and a second metal layer 202. In addition, although not shown in the drawing, the second pad part 212b also includes the first metal layer 201 and the second metal layer 202.

The first metal layer 201 is a seed layer of the first circuit pattern 210. In detail, the first metal layer 201 is a seed layer formed through electroless plating. The seed layer includes a metal material. For example, the seed layer may include copper.

In addition, the second metal layer 202 is a plating layer. In detail, the second metal layer 202 is a plating layer formed through electrolytic plating using the first metal layer 201 as a seed layer.

A thickness of the first metal layer 201 is smaller than a thickness of the second metal layer 202.

For example, the thickness of the first metal layer 201 may be 0.7 um to 2 um. In addition, the thickness of the second metal layer 202 may be 10 um to 25 um.

The first metal layer 201 and the second metal layer 202 may include a same metal material. For example, the first metal layer 201 and the second metal layer 202 may include copper (Cu).

A bonding layer 203 may be disposed on the second metal layer 201. In detail, the bonding layer 203 is disposed on a side surface of the first metal layer 201, a side surface of the second metal layer 202, and an upper surface of the second metal layer 202. That is, the bonding layer 203 is disposed while surrounding the first metal layer 201 and the second metal layer 202.

The bonding layer 203 includes a metal. For example, the bonding layer 203 may include tin (Sn).

A thickness of the bonding layer 203 may be 0.3 um to 0.7 um. The bonding layer 203 may increase a tin content while extending from a lower surface of the bonding layer 203 toward an upper surface of the bonding layer 203. A lower surface of the bonding layer 203 is a surface where the second metal layer 202 comes into contact.

Since the bonding layer 203 and the second metal layer 202 come into contact, the bonding layer 203 may increase a tin content while extending from the lower surface of the bonding layer 203 toward the upper surface of the bonding layer 203, and may decrease a copper content while extending from the lower surface of the bonding layer 203 toward the upper surface of the bonding layer 203.

Accordingly, the bonding layer 203 may have only pure tin remaining in a thickness range of 0.1 um to 0.3 um on an upper surface of the bonding layer 203.

A terminal of the chip, a terminal of the printed circuit board, and a terminal of the display panel are easily bonded to the first pad part and the second pad part by the bonding layer 203. In detail, the terminals and the pad parts are bonded by heat and pressure. That is, when heat and pressure are applied to the first pad part and the second pad part, an upper surface where pure tin remains in the bonding layer is melted. As a result, the terminals and the pad parts are easily bonded.

Accordingly, the bonding layer 203 is not separated from the first pad part 212a, but becomes a part of the first pad part 212a.

A thickness of the first circuit pattern 210 may be 2 um to 25 um. For example, the thickness of the first circuit pattern 210 may be 5 um to 20 um. For example, the thickness of the first circuit pattern 210 may be 7 um to 15 um.

The thickness of the first circuit pattern 210 may be different from a sum of thicknesses of the first metal layer 201, the second metal layer 202, and the bonding layer 203. In detail, a flash etching process is performed during a manufacturing process to separate the circuit patterns. Therefore, the first metal layer 201 is etched. Accordingly, a thickness of the first circuit pattern 210 finally manufactured is smaller than a sum of the thicknesses of the first metal layer 201, the second metal layer 202, and the bonding layer 203.

If the thickness of the first circuit pattern 210 and the second circuit pattern 220 is less than 2 um, a resistance of the first circuit pattern 210 and the second circuit pattern 220 increases. If the thickness of the first circuit pattern 210 and the second circuit pattern 220 exceeds 25 um, it is difficult to form a fine pattern.

Meanwhile, a buffer layer 205 may be further disposed between the substrate 100 and the first circuit pattern 210. An adhesion between the substrate 100 and the first circuit pattern 210 which is a heterogeneous material is improved by the buffer layer 205.

The buffer layer 205 may be formed in multiple layers. In detail, the buffer layer 205 includes a first buffer layer 205a and a second buffer layer 205b on the first buffer layer 205a. Accordingly, the first buffer layer 205a is in contact with the substrate 100. In addition, the second buffer layer 205b is in contact with the first circuit pattern 201.

The first buffer layer 205a may include a material having good adhesion to the substrate 100. For example, the first buffer layer 205a may include nickel (Ni). In addition, the second buffer layer 205b may include a material having good adhesion to the first circuit pattern 210. For example, the second buffer layer 205b may include chromium (Cr).

The buffer layer 205 may have a film thickness in nanometer units. For example, the thickness of the buffer layer 205 may be 20 nm or less.

The adhesion between the substrate 100 and the first circuit pattern 210 which is a heterogeneous material is improved by the buffer layer 205. Therefore, the first circuit pattern 201 is prevented from being delaminated.

Meanwhile, referring to FIG. 3, the bonding layer 203 may include a first bonding layer 203a and a second bonding layer 203b.

In detail, the first bonding layer 203a may be disposed on the first wiring part 211 and the first pad part 212a. In addition, although not shown in the drawing, the first bonding layer 203a may also be disposed on the second pad part 212b. That is, the first bonding layer 203a may be disposed on the first circuit pattern 210.

In addition, the second bonding layer 203b may be disposed only on the first pad part 212a and the second pad part 212b. That is, a layer structure of the first wiring part 211 and layer structures of the first pad part 212a and the second pad part 212b are changed by the second bonding layer 203b.

The first bonding layer 203a and the second bonding layer 203b may include a metal. In detail, the first bonding layer 203a and the second bonding layer 203b may include tin (Sn).

The first bonding layer 203a and the second bonding layer 203b may have different thicknesses. In detail, a thickness of the second bonding layer 203b may be greater than a thickness of the first bonding layer 203a.

For example, the first bonding layer 203a may have a thin film thickness of 0.02 um to 0.06 um. In addition, a thickness of the second bonding layer 203b may be 0.2 um to 0.6 um.

If the bonding layer is thickly disposed between the protective layer 300 and the first wiring part 211, cracks may occur when the flexible circuit board is bent. Accordingly, the first bonding layer 231 between the protective layer 300 and the first wiring part 211 is formed with a thin film thickness. Therefore, it is possible to prevent cracks from occurring when the flexible circuit board is bent.

In addition, the second bonding layer 203b may have a higher tin content as it extends from the lower surface to the upper surface. The lower surface of the second bonding layer 203b is a surface that contacts the first bonding layer 203a.

The second bonding layer 203b may have a higher tin content and a lower copper content as it extends from the lower surface to the upper surface. Accordingly, only pure tin may remain in the second bonding layer 203b in a thickness range of 0.1 um to 0.3 um on the upper surface of the second bonding layer 203b.

The terminal of the chip, the terminal of the printed circuit board, and the terminal of the display panel are easily bonded to the first pad part and the second pad part by the second bonding layer 203b. In detail, the terminals and the pad parts are bonded by heat and pressure. That is, when heat and pressure are applied to the first pad part and the second pad part, the upper surface where pure tin remains in the bonding layer is melted. As a result, the terminals and the pad parts are easily bonded.

Accordingly, the first bonding layer 203a and the second bonding layer 203b are not separated from the first pad part 212a, but become a part of the first pad part.

Meanwhile, the protective layer 300 is disposed on the wiring part of the first circuit pattern 210 and the wiring part of the second circuit pattern 220. In detail, the protective layer 300 is disposed while surrounding the first wiring part 211 and the second wiring part 221. That is, the protective layer 300 may be disposed on the first circuit pattern 210 and the second circuit pattern 220 excluding the first pad part, the second pad part, the third pad part, and the fourth pad part.

The protective layer 300 may include a solder paste. For example, the solder paste may include a thermosetting resin, a thermoplastic resin, a filler, a curing agent, or a curing accelerator.

Meanwhile, in the above description, the first circuit pattern 210 and the second circuit pattern 220 is disposed on a same surface of the substrate 100, but the embodiment is not limited thereto.

In detail, the first circuit pattern 210 and the second circuit pattern 220 may be disposed on different surfaces of the substrate 100. For example, the first circuit pattern 210 may be disposed on one surface of the substrate 100, and the second circuit pattern 220 may be disposed on another surface opposite to the one surface of the substrate 100.

Accordingly, the display panel is connected to the chip on one surface of the substrate 100. In addition, the printed circuit board is connected to the chip on another surface of the substrate 100.

Meanwhile, as described above, the chip CH is disposed on the chip mounting region CA. A terminal of the chip CH is electrically connected to the pad part of the first circuit pattern, the pad part of the second circuit pattern, and the pad part of the third circuit pattern, which are disposed in the inner region of the chip mounting region CA.

At this time, if the alignment of the terminal of the chip and the pad part of the first circuit pattern, the pad part of the second circuit pattern, and the pad parts of the third circuit pattern is misaligned, the connection characteristics of the chip and the circuit pattern are reduced. In addition, it is difficult to implement the alignment of the terminal of the chip and the pad part of the first circuit pattern, the pad part of the second circuit pattern, and the pad parts of the third circuit pattern to be all the same in terms of a process.

Accordingly, the alignment of the terminal and the pad part that can easily proceed with a process while satisfying the characteristics of the COF module is described below.

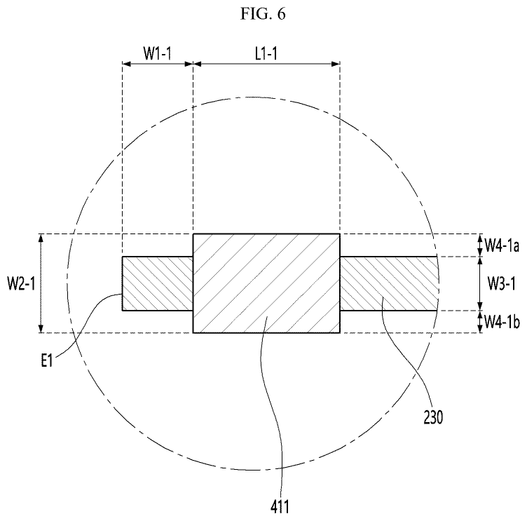

FIG. 5 is a drawing for explaining region A of FIG. 1. That is, FIG. 1 is a drawing for explaining the chip mounting region of the flexible printed circuit board.

Referring to FIG. 5, the first pad part 212a, the second pad part 212b, and the third circuit pattern 230 are disposed inside the chip mounting region CA.

In addition, the first terminal part 410 and the second terminal part 420 of the chip CH are disposed inside the chip mounting region CA. The first terminal part 410 is connected to the pad part of the third circuit pattern 230. The second terminal part 420 is connected to the first pad part 212a and the second pad part 212b.

The terminal part of the chip CH and the pad part are bonded by applying heat of a set size using a solder. Since the substrate 100 includes a resin material, the substrate 100 may contract in the third direction 3D and the fourth direction 4D due to the heat. Therefore, an alignment of the terminal part of the chip and the pad part may be misaligned due to the contraction of the substrate 100. Accordingly, before bonding the terminal part and the pad part, a compensation value considering the contraction of the substrate can be set and then bonded. Accordingly, the terminal part of the chip and the pad part can be bonded while satisfying the alignment within a set range.

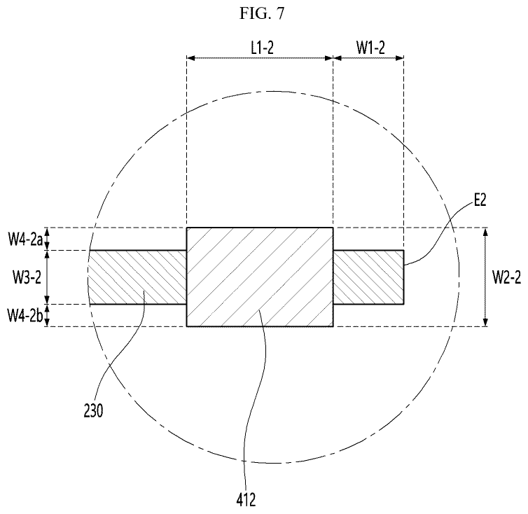

FIGS. 6 and 7 are drawings for explaining the alignment of the third circuit pattern 230 and the first terminal part 410.

Referring to FIG. 6, the first-first terminal part 411 is spaced apart from a first end E1 of the third circuit pattern 230. In detail, the first-first terminal part 411 is spaced apart from the first end E1 of the third circuit pattern 230 by a first-first width W1-1. Here, the first-first width W1-1 is defined as a maximum separation distance between the first-first terminal part 411 and the first end E1 of the third circuit pattern 230.

The first-first width W1-1 may be different from a length L1-1 of the first-first terminal part 411. In detail, the first-first width W1-1 may be smaller than the length L1-1 of the first-first terminal part 411.

For example, the first-first width W1-1 may be 5 um or more. In detail, the first-first width W1-1 may be 5 um to 20 um. More specifically, the first-first width W1-1 may be 8 um to 17 um. In more detail, the first-first width W1-1 may be 10 μm to 15 μm.

Since the first-first terminal part 411 and the first end E1 of the third circuit pattern 230 are spaced apart from each other and disposed, the first-first terminal part 411 and the pad part of the third circuit pattern 230 can be prevented from non-overlapping in a longitudinal direction of the third circuit pattern 230. Accordingly, the first-first terminal part 411 is stably bonded to the pad part of the third circuit pattern.

In addition, since the separation distance between the first-first terminal part 411 and the first end E1 of the third circuit pattern 230 is smaller than the length L1-1 of the first-first terminal part 411, a length of the third circuit pattern 230 can be prevented from increasing. Accordingly, a size of the chip mounting region CA can be reduced. In addition, the first pad part, the second pad part, and the third circuit pattern can be disposed with a sufficient spacing within the chip mounting region CA.

The first-first terminal part 411 includes an overlapping region and a non-overlapping region. The overlapping region is defined as a region overlapping the third circuit pattern in a width direction of the third circuit pattern 230. In addition, the non-overlapping region is defined as a region that does not overlap the third circuit pattern in the width direction of the third circuit pattern 230. The non-overlapping region may include two non-overlapping regions.

The overlapping region is formed with a third-first width W3-1. The third-first width W3-1 may correspond to a width of the third circuit pattern. In addition, the non-overlapping region is formed with a fourth-first(a) width W4-1a and a fourth-first(b) width W4-1b.

The fourth-first(a) width W4-1a and the fourth-first(b) width W4-1b may be smaller than the width W2-1 of the first-first terminal part 411. In addition, the fourth-first(a) width W4-1a and the fourth-first(b) width W4-1b may be smaller than the third-first width W3-1.

In detail, the fourth-first(a) width W4-1a and the fourth-first(b) width W4-1b may be 0.3 times or less, 0.2 times or less, or 0.1 times or less than the width W2-1 of the first-first terminal part 411. When the fourth-first(a) width W4-1a and the fourth-first(b) width W4-1b exceed 0.3 times the width W2-1 of the first-first terminal part 411, connection characteristics of the chip and the third circuit pattern may be reduced by a region where the first-first terminal part 411 and the pad part of the third circuit pattern are not bonded.

In addition, the fourth-first(a) width W4-1a and the fourth-first(b) width W4-1b may be 0.4 times or less, 0.3 times or less, 0.2 times or less, or 0.1 times or less than the third-first width W3-1. If the fourth-first(a) width W4-1a and the fourth-first(b) width W4-1b exceed 0.4 times the third-first width W3-1, the connection characteristics of the chip and the third circuit pattern may be reduced due to a region where the first-first terminal part 411 and the pad part of the third circuit pattern are not bonded.

For example, the width W2-1 of the first-first terminal part 411 may be 10 um to 50 um. In addition, the third-first width W3-1 may be 5 um to 25 um. In addition, the fourth-first(a) width W4-1a and the fourth-first(b) width W4-1b may be 2 um to 10 um. The width W2-1 of the first-first terminal part 411, the third-first width W3-1, the fourth-first(a) width W4-1a, and the fourth-first(b) width W4-1b may satisfy the above condition within the above range.

The fourth-first(a) width W4-1a and the fourth-first(b) width W4-1b may be the same. Alternatively, the fourth-first(a) width W4-1a and the fourth-first(b) width W4-1b may be different. In addition, a difference between the fourth-first(a) width W4-1a and the fourth-first(b) width W4-1b may be 10% or less, 5% or less, or 3% or less.

If a difference between the fourth-first(a) width W4-1a and the fourth-first(b) width W4-1b exceeds 10%, the first terminal part 410 is disposed to be biased in one direction on the pad part of the third circuit pattern. Accordingly, an overall alignment of the first terminal part 410 may be misaligned.

Referring to FIG. 7, the first-second terminal part 412 is spaced apart from the second end E2 of the third circuit pattern 230. In detail, the first-second terminal part 412 is spaced apart from a second end E2 of the third circuit pattern 230 by a first-second width W1-2. Here, the first-second width W1-2 is defined as a maximum separation distance between the first-second terminal part 412 and the second end E2 of the third circuit pattern 230.

The first-second width W1-2 may be different from a length L1-2 of the first-second terminal part 412. In detail, the first-second width W1-2 may be smaller than the length L1-2 of the first-second terminal part 412.

For example, the first-second width W1-2 may be 5 um or more. In detail, the first-second width W1-2 may be 5 um to 20 um. In more detail, the first-second width W1-2 may be 8 um to 17 um. In more detail, the first-second width W1-2 may be 10 um to 15 um.

Since the first-second terminal part 412 and the second end E2 of the third circuit pattern 230 are spaced apart from each other, the pad part of the first-second terminal part 412 and the third circuit pattern 230 can be prevented from overlapping in the longitudinal direction of the third circuit pattern 230. Accordingly, the first-second terminal part 412 is stably bonded to the pad part of the third circuit pattern.

In addition, since a separation distance between the first-second terminal part 412 and the second end E2 of the third circuit pattern 230 is smaller than the length L1-2 of the first-second terminal part 412, a length of the third circuit pattern 230 can be prevented from increasing. Accordingly, the size of the chip mounting region CA can be reduced. In addition, the first pad part, the second pad part, and the third circuit pattern can be disposed with a sufficient spacing therebetween within the chip mounting region CA.

The first-second terminal part 412 includes an overlapping region and a non-overlapping region. The overlapping region is defined as a region that overlaps the third circuit pattern in a width direction of the third circuit pattern 230. In addition, the non-overlapping region is defined as a region that does not overlap the third circuit pattern in the width direction of the third circuit pattern 230. The non-overlapping region may include two non-overlapping regions.

The overlapping region is formed with a third-second width W3-2. The third-second width W3-2 may correspond to the width of the third circuit pattern. In addition, the non-overlapping region is formed with a fourth-second(a) width W4-2a and a fourth-second(b) width W4-2b.

The fourth-second(a) width W4-2a and the fourth-second(b) width W4-2b may be smaller than the width W2-2 of the first-second terminal part 412. In addition, the fourth-second(a) width W4-2a and the fourth-second(b) width W4-2b may be smaller than the third-second width W3-2.

In detail, the fourth-second(a) width W4-2a and the 4-2 width W4-2b may be 0.3 times or less, 0.2 times or less, or 0.1 times or less than the width W2-2 of the first-second terminal part 412. If the fourth-second(a) width W4-2a and the fourth-second(b) width W4-2b exceed 0.3 times the width W2-2 of the first-second terminal part 412, the connection characteristics of the chip and the third circuit pattern may be reduced by a region where the first-second terminal part 412 and the pad part of the third circuit pattern are not bonded.

In addition, the fourth-second(a) width W4-2a and the fourth-second(b) width W4-2b may be 0.4 times or less, 0.3 times or less, 0.2 times or less, or 0.1 times or less than the third-second width W3-2. If the fourth-second(a) width W4-2a and the fourth-second(b) width W4-2b exceed 0.4 times the third-second width W3-2, the connection characteristics of the chip and the third circuit pattern may be reduced by a region where the first-second terminal part 412 and the pad part of the third circuit pattern are not bonded.

For example, the width W2-2 of the first-second terminal part 412 may be 10 μm to 50 μm. In addition, the third-second width W3-2 may be 5 um to 25 um. In addition, the fourth-second(a) width W4-2a and the fourth-second(b) width W4-2b may be 2 um to 10 um. The width W2-2 of the first-second terminal part 412, the third-second width W3-2, the fourth-second(a) width W4-2a, and the fourth-second(b) width W4-2b may satisfy the above condition within the above range.

The fourth-second(a) width W4-2a and the fourth-second(b) width W4-2b may be the same. Alternatively, the fourth-second(a) width W4-2a and the fourth-second(b) width W4-2b may be different. In addition, a difference between the fourth-second(a) width W4-2a and the fourth-second(b) width W4-2b may be 10% or less, 5% or less, or 3% or less.

If the difference between the fourth-second(a) width W4-2a and the fourth-second(b) width W4-2b exceeds 10%, the first-second terminal part 412 is disposed to be biased in one direction on the pad part of the third circuit pattern. Accordingly, an overall alignment of the first-second terminal part 412 may be misaligned, which may affect the alignment of other terminal parts.

The first-first width W1-1 and the first-second width W1-2 may be the same. Alternatively, the first-first width W1-1 and the first-second width W1-2 may be different. In addition, the difference between the first-first width W1-1 and the first-second width W1-2 may be 10% or less, 5% or less, or 3% or less.

If the difference between the first-first width W1-1 and the first-second width W1-2 exceeds 10%, the first terminal part 411 and 412 is disposed to be biased in one direction on the pad part of the third circuit pattern. Accordingly, the overall alignment of the first terminal part 411 and 412 may be misaligned, which may affect the alignment of other terminal parts.

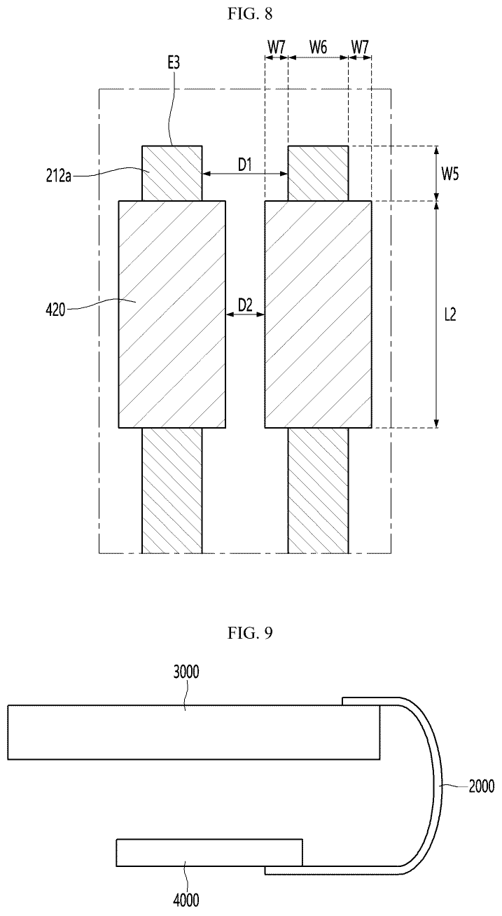

FIG. 8 is a drawing for explaining an alignment of the first circuit pattern 210, the second circuit pattern 220, and the second terminal part 410. In FIG. 8, a description is based on the first pad part 212a of the first circuit pattern 210, but the embodiment is not limited thereto. The description of FIG. 8 can be equally applied to the third pad part 222a of the second circuit pattern 220.

Referring to FIG. 8, the second terminal part 420 is spaced apart from an end E3 of the first pad part 212a. In detail, the second terminal part 420 is spaced apart from the end E3 of the first pad part 212a by a fifth width W5. Here, the fifth width W5 is defined as a maximum separation distance between the second terminal part 420 and the end E3 of the first pad part 212a.

The fifth width W5 may be different from a length L2 of the second terminal part 420. In detail, the fifth width W5 may be smaller than the length L2 of the second terminal part 420.

Since the second terminal part 420 and the third end E3 of the first pad part 212a are spaced apart from each other, the second terminal part 420 and the first pad part 212a can be prevented from non-overlapping in the longitudinal direction of the first pad part 212a. Accordingly, the second terminal part 420 is stably bonded to the first pad part 212a.

In addition, since the separation distance between the second terminal part 420 and the end E3 of the first pad part 212a is smaller than the length L2 of the second terminal part 420, the length of the first pad part 212a can be prevented from increasing. Accordingly, the size of the chip mounting region CA can be reduced. In addition, the first pad part, the second pad part, and the third circuit pattern may be disposed with a sufficient spacing within the chip mounting region CA.

The second terminal part 420 includes an overlapping region and a non-overlapping region. The overlapping region is defined as a region that overlaps the first pad part 212a in a width direction of the first pad part 212a. In addition, the non-overlapping region is defined as a region that does not overlap the first pad part 212a in the width direction of the first pad part 212a. The non-overlapping region may include two non-overlapping regions.

The overlapping region is formed with a sixth width W6. The sixth width W6 may correspond to the width of the first pad part 212a. In addition, the non-overlapping region is formed with a seventh width W7.

The seventh width W7 may be smaller than the sixth width W6.

In detail, the seventh width W7 may be 0.2 times or less or 0.1 times or less than the sixth width W6. If the seventh width W7 exceeds 0.2 times the sixth width W6, the connection characteristics of the chip and the third circuit pattern may be reduced due to a region where the second terminal part 420 and the first pad part 212a are not bonded. In addition, a distance from the adjacent first pad part 212a may be reduced, resulting in a short circuit.

In addition, the seventh width W7 may be different from a spacing D1 of an adjacent first pad part 212a. In detail, the seventh width W7 may be smaller than the spacing D1 of the adjacent first pad part 212a.

In addition, the seventh width W7 may be different from a spacing D2 of an adjacent second terminal part 420. In detail, the seventh width W7 may be smaller than a spacing D2 of the adjacent second terminal part 420.

Since the seventh width W7 is smaller than the spacing D1 of the first pad part 212a and the spacing D2 of the second terminal part 420, the spacing D1 of the first pad part 212a and the spacing D2 of the second terminal part 420 can be sufficiently secured. Accordingly, the spacing of the adjacent first pad part or the adjacent first terminal part is sufficiently secured. Therefore, it is possible to prevent a short circuit from occurring during a bonding process of the chip and the pad part.

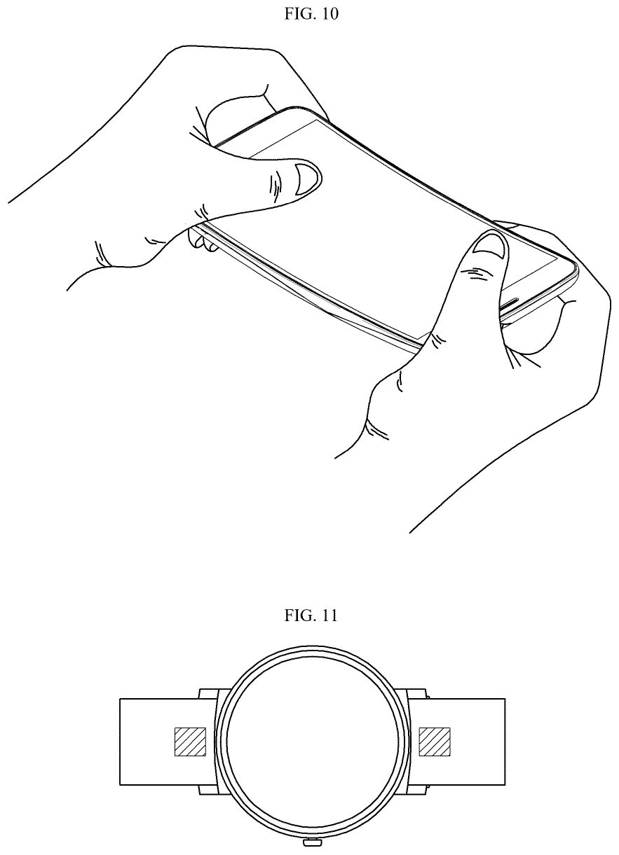

Referring to FIG. 9, a COF module 2000 according to an embodiment includes the flexible circuit board. One end of the COF module 2000 is connected to the display panel 3000. In addition, the other end of the COF module 2000 is connected to the printed circuit board 4000.

The COF module 2000, the display panel 3000, and the printed circuit board 4000 may be directly or indirectly connected.

For example, an anisotropic conductive film may be disposed between the COF module 2000 and the printed circuit board 4000. The COF module 2000 and the printed circuit board 4000 may be electrically connected while being bonded by the anisotropic conductive film. The anisotropic conductive film may be a resin in which conductive particles are dispersed. Therefore, an electrical signal connected by the printed circuit board 4000 can be transmitted to the COF module 2000 through the conductive particles included in the anisotropic conductive film.

The COF module 1000 includes a flexible substrate. Therefore, the COF module 1000 can have a rigid or bent form between the display panel 3000 and the printed circuit board 4000.

The COF module 2000 can connect the display panel 3000 and the printed circuit board 4000 that are disposed opposite each other in a bent form. Therefore, the thickness of the electronic device can be reduced. In addition, a degree of freedom of design can be improved. In addition, the wiring of the COF module 2000 does not break even in a bent form. Therefore, the reliability of the electronic device including the COF module can be improved.

Since the COF module is flexible, it can be used in various electronic devices.

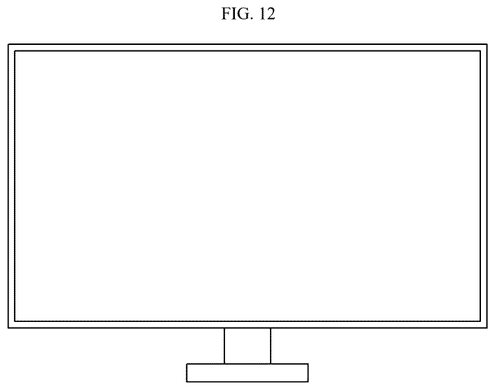

For example, referring to FIG. 10, the COF module can be applied to a flexible touch window that bends. Therefore, a touch device including the COF module can be a flexible touch device. Therefore, a user can bend or fold it by a hand. Such a flexible touch window can be applied to a wearable touch, etc.

Referring to FIG. 11, the COF module can be included in various wearable touch devices including a curved display. Therefore, an electronic device including the COF module can be slimmed down or made lightweight.

Referring to FIG. 12, the COF module can be used in various electronic devices having a display portion, such as a TV, a monitor, and a laptop. At this time, the COF module can also be used in an electronic device having a curved display portion.

However, the embodiment is not limited thereto, and the flexible printed circuit board and the COF module including the same can be used in various electronic devices.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A COF module comprising:
a substrate including a chip mounting region;
a circuit pattern disposed on the substrate; and
a chip disposed on the chip mounting region and including a terminal part connected to the circuit pattern,
wherein the circuit pattern includes a routing pattern disposed on the chip mounting region,
wherein the routing pattern includes a first routing pad corresponding to one end of the routing pattern, a second routing pad corresponding to another end of the routing pattern, and a routing connection pattern connecting the first routing pad and the second routing pad,
wherein the first routing pad and the second routing pad are disposed on the chip mounting region,
wherein the terminal part of the chip includes a first-first terminal connected to the first routing pad, and a first-second terminal connected to the second routing pad, and
wherein at least one of an end of the first-first terminal and an end of the first-second terminal is misaligned along a vertical direction with at least one of an end of the first routing pad and an end of the second routing pad.

2. The COF module of claim 1, wherein the end of the first-first terminal and the end of the first routing pad are misaligned along the vertical direction.

3. The COF module of claim 2, wherein the end of the first-second terminal and the end of the second routing pad are misaligned along the vertical direction.

4. The COF module of claim 3, wherein the end of the first-first terminal is closer to the second routing pad than the end of the first routing pad.

5. The COF module of claim 4, wherein the end of the first-second terminal is closer to the first routing pad than the end of the second routing pad.

6. The COF module of claim 3, wherein a first separation distance between the end of the first-first terminal and the end of the first routing pad is smaller than a length of the first-first terminal.

7. The COF module of claim 6, wherein a second separation distance between the end of the first-second terminal and the end of the second routing pad is smaller than a length of the first-second terminal.

8. The COF module of claim 7, wherein each of the first separation distance and the second separation distance is 5 um to 20 um.

9. The COF module of claim 1, wherein the first-first terminal includes:
a first overlapping region overlapping the first routing pad along the vertical direction,
a first non-overlapping region extending from a first side of the first overlapping region in a width direction of the first routing pad and not overlapping the first routing pad along the vertical direction, and
a second non-overlapping region extending from a second side of the first overlapping region in the width direction and not overlapping the first routing pad along the vertical direction, and
wherein a width of the first overlapping region is greater than a width of the first non-overlapping region and a width of the second non-overlapping region.

10. The COF module of claim 1, wherein the first-second terminal includes:
a second overlapping region overlapping the second routing pad along the vertical direction,
a third non-overlapping region extending from a first side of the second overlapping region in a width direction of the second routing pad and not overlapping the second routing pad along the vertical direction, and
a fourth non-overlapping region extending from a second side of the second overlapping region in the width direction of the second routing pad and not overlapping the second routing pad along the vertical direction, and
wherein a width of the second overlapping region is greater than a width of the third non-overlapping region and a width of the fourth non-overlapping region.

11. The COF module of claim 10, wherein the width of the first non-overlapping region and the width of the second non-overlapping region are 0.4 times or less than the width of the first overlapping region.

12. The COF module of claim 10, wherein the width of the third non-overlapping region and the width of the fourth non-overlapping region are 0.4 times or less than the width of the second overlapping region.

13. The COF module of claim 11, wherein the width of the first non-overlapping region and the width of the second non-overlapping region are different from each other.

14. The COF module of claim 11, wherein the width of the third non-overlapping region and the width of the fourth non-overlapping region are different from each other.

15. The COF module of claim 1, wherein the routing connection pattern is disposed entirely on the chip mounting region.

16. The COF module of claim 1, wherein the circuit pattern includes a wiring pattern having one end disposed on the chip mounting region and another end disposed outside the chip mounting region,
wherein the wiring pattern includes a wiring pad part corresponding to the one end of the wiring pattern,
wherein the chip includes a second terminal part connected to the wiring pad part, and
wherein an end of the wiring pad part and an end of the second terminal part are misaligned along a vertical direction.

17. The COF module of claim 16, wherein a third separation distance between the end of the second terminal part and the end of the wiring pad part is smaller than a length of the second terminal part.

18. The COF module of claim 17, wherein the second terminal part includes:
a third overlapping region that overlaps the wiring pad part along the vertical direction,
a fifth non-overlapping region extending in a width direction of the wiring pad part from a first side of the third overlapping region and not overlapping the wiring pad part along the vertical direction, and
a sixth non-overlapping region extending in the width direction of the wiring pad part from a second side of the third overlapping region and not overlapping the wiring pad part along the vertical direction, and
wherein a width of the third overlapping region is greater than a width of the fifth non-overlapping region and a width of the sixth non-overlapping region.

19. The COF module of claim 18, wherein the width of the fifth non-overlapping region and the width of the sixth non-overlapping region are different from each other.

20. An electronic device comprising:
a COF module according to claim 1;
a printed circuit board connected to the first circuit pattern; and
a display panel connected to the second circuit pattern.
